(19) United States
(12) Patent Application Publication
(10) Pub. No.: US 2005/0276029 A1
(43) Pub. Date: Dec. 15, 2005

(54) Mounting a voltage regulator on top of a processor

(76) Inventor: David L. Lober, Chandler, AZ (US)

Correspondence Address: TROP PRUNER & HU, PC, 8554 KATY FREEWAY, SUITE 100, HOUSTON, TX, 77024, US

(21) Appl. No.: 10/866,839

(22) Filed: Jun. 14, 2004

(51) Int. Cl. H05K 1/18; H01R 12/16

(52) U.S. Cl. 361/769; 361/720; 439/74

(57) ABSTRACT

A voltage regulator board may be mounted over a processor package on a motherboard. In some embodiments, this on top mounting may save space and may improve voltage power delivery. A voltage regulator interconnect may have a first upper level which contacts the voltage regulator board, in one embodiment, and a second lower contact which receives contacts on the lower side of the processor package. The processor package may then make contact through the voltage regulator interconnect directly to the motherboard. The contacts on the voltage regulator interconnect simply short power from the voltage regulator board through appropriate contacts on the processor package.

### BACKGROUND

This invention relates generally to providing power to microprocessors.

Power delivery to increasingly power dissipative microprocessors seem to require growing the processor package body size to accommodate an increased number of package power and ground contacts. The voltage regulator module may connect to the processor package with cables, via top package power/ground pads or via bottom package power/ground pads.

Problems with existing approaches include requiring that the processor package be larger, providing more room or space on the motherboard for the voltage regulator and processor connection, and/or spacing the voltage regulator from the processor. Spacing the voltage regulator from the processor may reduce power delivery performance.

Thus, there is a need for better ways to provide power to microprocessors.

### BRIEF DESCRIPTION OF THE DRAWINGS

FIG. 1 is an enlarged, cross-sectional view through one embodiment of the present invention;

FIG. 2 is an enlarged, exploded view of the embodiment shown in FIG. 1;

FIG. 3 is an enlarged, cross-sectional view taken generally along the line 3-3 in FIG. 4; and

FIG. 4 is a top plan view of a voltage regulator interconnect in accordance with one embodiment of the present invention.

### DETAILED DESCRIPTION

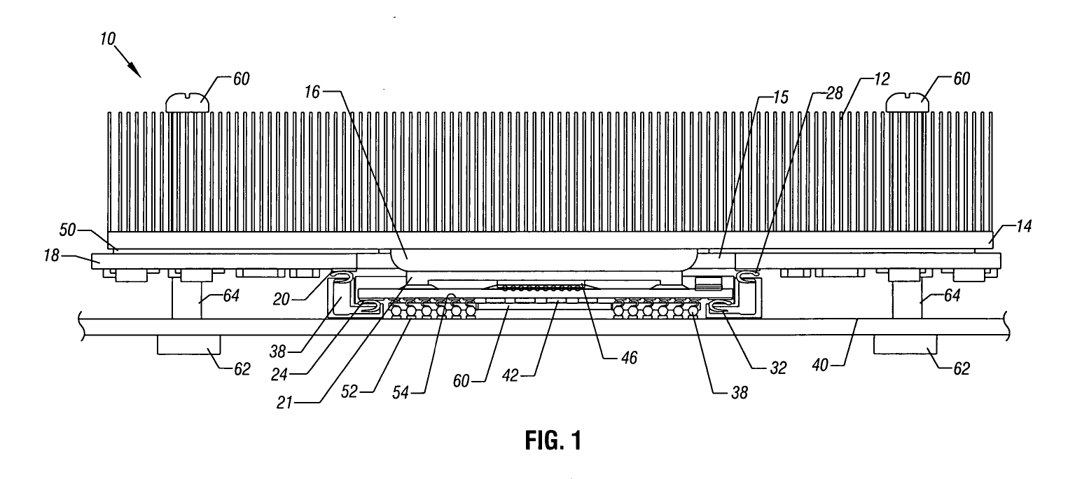

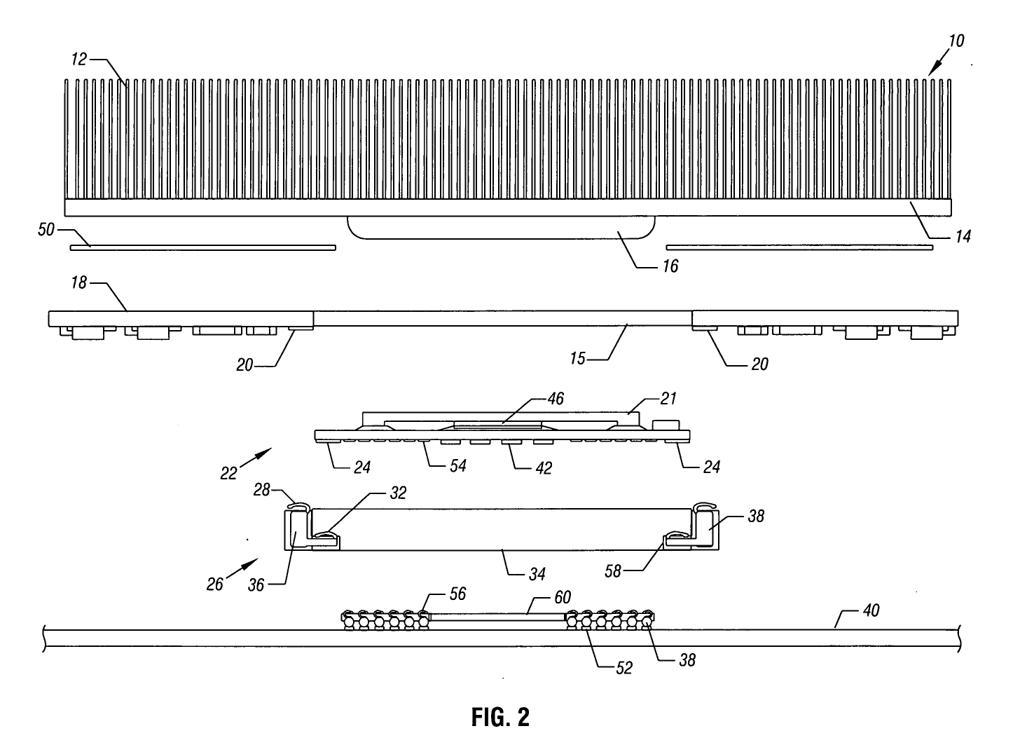

Referring to FIGS. 1 and 2, a heat sink 10 may include upstanding fins 12, a base 14, and a downwardly extending prong 16. The prong 16 may be circularly shaped and may have rounded edges in one embodiment.

The prong 16 extends through a mating opening in the thermal interface material 50. As shown in FIG. 1, the thermal interface material 50 is sandwiched between the heat sink base 14 and a voltage regulator board 18 in accordance with one embodiment of the present invention. In that embodiment, there may be downward pressure applied between the heat sink base 14 and the voltage regulator board 18 through the thermal interface material 50. The thermal interface material 50 may aid in removing heat from the voltage regulator board 18 to the heat sink base 14 in one embodiment of the present invention.

The prong 16 extends through a mating opening 15 in the voltage regulator board 18. The voltage regulator board 18 also includes a set of downwardly extending contacts 20 which extend around the opening 15 in the voltage regulator board 18.

The prong 16 extends through the opening 15 to contact the lid 21 which mounts the processor 46 on the processor package 22. Central contacts 42 extend downwardly from the lower side of the package 22. Peripheral contacts 24 also extend downwardly from the package 22.

The voltage regulator interconnect 26 receives the processor package 22, makes electrical contact therewith, and also, simultaneously, makes electrical contact with the contacts 20 on the voltage regulator board 18. It does so by making electrical contact with the contacts 24 on the processor package 22 through lower contacts 32 mounted on the frame 34. At the same time, the voltage regulator board 18 contacts 20 contact the upper set of contacts 28 on the interconnect 26.

In one embodiment, the contacts 28 and 32 may be implemented by circular, U-shaped, upwardly extending, spring contacts. However, other contact designs may also be utilized. The contacts 28 are arranged on a first surface above and spaced outwardly from a second surface that includes said contacts 32.

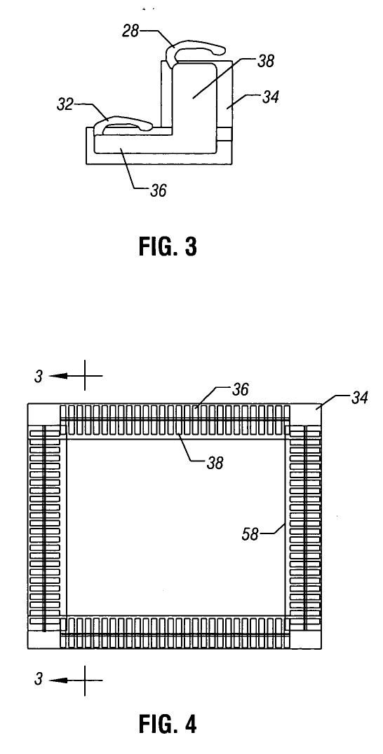

The contacts 28 and 32 are shorted through the L-shaped contact plate 36 which includes an upstanding portion 38 that connects to the contact 28 of a contact pair and a horizontal portion which connects to the lower contact 32, as shown in FIG. 3. Thus, one contact 20 on the voltage regulator board 18 is shorted to one contact 24 on the processor package 22 to supply processor power.

At the same time, the voltage regulator board 18 may mount over the processor package 22, saving real estate and reducing the distance between the voltage regulator board 18 and the processor 46, which may improve power delivery performance in some embodiments.

The voltage regulator interconnect body 34 may be mounted on the motherboard 40. The voltage regulator interconnect 26 may be adhesively secured, may be surface mounted, or may be held by stakes in some embodiments of the present invention to the motherboard 40. In other embodiments, the interconnect may not be fixed to the motherboard 40.

The loading of the interconnect 26 onto the motherboard 40 and its precise positioning may be aided, in some embodiments, by providing an opening 58 (FIGS. 1 and 4) in the frame 34 which interacts with and is guided into position on the motherboard 40 by the socket 60. In one embodiment, the socket 60 may be first surface mounted to the motherboard 40. Thereafter, the interconnect 26 may be positioned on the motherboard 40, aligned by the socket 60. The remaining components are plugged into and are aligned by the interconnect 26 and prong 16. The prong 16 also presses the processor package 22 and board 18 into good contact with the interconnect 26.

The entire assembly is held together, as shown in FIG. 1, by fasteners such as the spring biased screws having screw heads 60 above the heat sink 10 and shanks 64, together with the nuts 62 below the motherboard 40. The springs (not shown) within the fasteners provide the compression force to activate the spring biased electrical contacts, including the contacts 28 and 32, as well as the contacts 56.

The socket 60 may have contacts 56 which make electrical contact with the contacts 54 on the processor package 22. On its opposite or lower side, the socket 60 may have solder balls 38 which make electrical contact with contacts 52 on the motherboard 40. In one embodiment of the present invention, the socket 60 may be a land grid array (LGA) socket, but any other socket designs may also be utilized in some embodiments of the present invention.

The interconnect 26 may be formed by stamping out the contacts 28 and 32, for example, from a copper sheet. The body 34 may be injection molded in one embodiment. The plates 36 and contacts 28 and 32 may be press fit into the body 34.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
mounting a voltage regulator board atop a processor package on a motherboard.

2. The method of claim 1 including providing a voltage regulator interconnect with a first set of contacts on a first surface and a second set of contacts on a second surface, said second surface being vertically displaced with respect to said first surface.

3. The method of claim 2 including providing a vertical plate which electrically couples said first and second contacts.

4. The method of claim 2 including providing a processor package with contacts that contact said second set of contacts.

5. The method of claim 4 including providing contacts on a voltage regulator board to contact said first set of contacts.

6. The method of claim 1 including providing a heat sink over said voltage regulator board.

7. The method of claim 6 including providing a projection on the downwardly facing surface of said heat sink.

8. The method of claim 7 including pressing said projection against said processor package to electrically couple said package to said second set of contacts.

9. The method of claim 8 including providing a land grid array socket on a motherboard and electrically connecting said land grid array socket to said processor package.

10. The method of claim 9 including providing spring contacts on said socket.

11. The method of claim 10 including guiding said interconnect onto said motherboard using said socket.

12. An interconnect to electrically couple a voltage regulator board to a processor package on a motherboard comprising:
a body;
a first surface including a plurality of contacts formed thereon to contact the processor package;
a second surface over said first surface and spaced outwardly therefrom, said second surface including a plurality of contacts to contact the voltage regulator board; and
a contact plate to electrically couple a contact on said first surface to a contact on said second surface.

13. The interconnect of claim 12 wherein said contacts on said first and second surfaces are spring contacts.

14. The interconnect of claim 13 wherein said spring contacts are circular.

15. The interconnect of claim 12 wherein said body has a central opening.

16. An electronic device comprising:
a motherboard;
a socket surface mounted to said motherboard;
an interconnect around said socket, said interconnect including a body, a first surface including a plurality of contacts formed thereon, a second surface over said first surface and spaced outwardly therefrom, said second surface including a plurality of contacts, and a contact plate to electrically couple a contact on said first surface to a contact on said second surface;
a processor package including contacts contacting said contacts on said first surface;
a voltage regulator board mounted over said processor package and including contacts that contact the contacts on said second surface; and
a heat sink mounted over said voltage regulator board.

17. The device of claim 16 wherein said heat sink includes a plurality of fins, a base, and a downwardly extending prong, said fins coupled to said base.

18. The device of claim 17 wherein said voltage regulator board includes a central opening and said prong extends through said central opening to contact said processor package.

19. The device of claim 16 including contacts on said motherboard, and contacts on said socket that contact contacts on said processor package.

20. The device of claim 16 wherein said interconnect includes a central opening, electrical contact being made between said motherboard and said processor package through said central opening in said interconnect.
